(19) United States
(12) Patent Application Publication
(10) Pub. No.: US 2007/0279885 A1
(43) Pub. Date: Dec. 6, 2007

(54) Backages with buried electrical feedthroughs

(76) Inventors: Nagesh R. Basavanhally, Skillman, NJ (US); Christopher D. W. Jones, New Providence, NJ (US); David Andrew Ramsey, Maplewood, NJ (US)

Correspondence Address: Lucent Technologies, Inc.;Docket Administrator - Room 3J-219, 101 Crawfords Corner Road, Holmdel, NJ, 07733-3030, US

(21) Appl. No.: 11/444,860

(22) Filed: May 31, 2006

(51) Int. Cl. H05K 7/14

(52) U.S. Cl. 361/799

(57) ABSTRACT

Apparatus include a substrate having a top surface, a housing having an inner surface, and a joint located between the housing and the substrate. The top and inner surfaces are located to form a cavity between the housing and the substrate. The joint is located to seal the cavity. The apparatus includes a micro-electronic structure that is exposed to the cavity and is located between the substrate and housing. The apparatus also includes a dielectric layer located over the substrate and electrical feedthroughs that traverse the joint and connect to the micro-electronic structure. Portions of the electrical feedthroughs that traverse the joint are located in trenches in the dielectric layer. The electrical feedthroughs have a density along part of the joint of at least 10 per millimeter.

### BACKGROUND

1. Technical Field

The invention relates generally to packaging, and more specifically, to packaged micro-electronic devices and methods for packaging micro-electronic, optical, and/or MEMS devices.

2. Discussion of Related-Art

This section introduces aspects that may be helpful to understanding the inventions. Accordingly, the statements of this section are to be read in this light and are not to be understood as admissions about what is prior art or what is not prior art.

Silicon has been used as a packaging platform for MEMS devices. On the silicon-packaging platform, one challenge is the fabrication of hermetically sealed packages that have electrical connections to the micro-electronic devices in the packages. The techniques available for making hermetically sealed packages potentially include anodic bonding, fusion bonding, solder bonding, and glass-frit bonding. Some of the techniques for making the connections to micro-electronic devices in packages include forming electrical connections in through-wafer vias, i.e., so that electrical pathways exit through the backside of the silicon substrate.

### BRIEF SUMMARY

In a first aspect, an apparatus includes a substrate having a top surface, a housing having an inner surface, and a joint located between the housing and the substrate. The top and inner surfaces are located to form a cavity between the housing and the substrate. The apparatus also includes a dielectric layer located over the substrate and electrical feedthroughs that traverse the joint and connect to the micro-electronic structure. Portions of the electrical feedthroughs that traverse the joint are located in trenches in the dielectric layer. The electrical feedthroughs have a density along part of the joint of at least 10 per millimeter.

In a second aspect, an apparatus includes a semiconductor substrate having a top surface, a housing having an inner surface, and a joint located between the housing and the substrate. The top and inner surfaces are located to form a cavity between the housing and the substrate. The apparatus includes a micro-electronic structure that is exposed to the cavity and that is located between the substrate and housing and a dielectric layer located over the substrate. The apparatus also includes electrical feedthroughs that traverse the joint and are connected to the micro-electronic structure. Portions of the electrical feedthroughs that traverse the joint are located in trenches in the dielectric layer. The dielectric layer insulates the electrical feedthroughs from the substrate.

In a third aspect, a method of packaging a micro-electronic structure includes forming electrical feedthroughs that connect to a micro-electronic structure located over a substrate. The forming of each electrical feedthrough includes depositing conducting material in a trench in a dielectric layer. The dielectric layer is located over the substrate. The method also includes forming a package by joining a housing to the substrate such that the micro-electronic structure is exposed to a cavity formed between the housing and the substrate. The step of joining includes forming a joint between the housing and the substrate. A portion of each trench traverses the joint.

Various embodiments provide electronic devices in which electrical feedthroughs traverse a joint between two parts of a package and methods of fabricating such packages. Some such fabrication methods can reduce sizes of gaps between conducting material of the electrical feedthroughs and the adjacent dielectric. For that reason, such fabrication methods may reduce the risk of gas leakage in final packages. Indeed, some such packages may be hermetic even when the electrical feedthroughs have large height-to-width aspect ratios and/or are densely spaced. Large height-to-width aspect ratios and dense spacings may be, e.g., desirable for the electrical feedthroughs that connect two-dimensional array-type devices with many elements to exteriors of packages.

### BRIEF DESCRIPTION OF THE DRAWINGS

FIG. 1 is a cross-sectional view of one embodiment of a packaged micro-electronic device in which electrical feedthroughs traverse the package's joint;

FIG. 2 is a cross-sectional view of a portion of the packaged micro-electronic device of FIG. 1 that illustrates the joint;

FIG. 3 is an oblique cut-away view of a specific embodiment of the packaged micro-electronic device of FIGS. 1-2;

FIG. 4A is a top view of an exemplary semiconductor substrate that was prepared to test features of the packaged micro-electronic devices of FIGS. 1-3;

FIG. 4B is an oblique view of tiered gold wire bonds that may be used in the packaged micro-electronic device of FIGS. 1-4A and the packaging method of FIG. 5;

FIG. 5 is a flow chart that illustrates a method of packaging a micro-electronic device, e.g., to make some embodiments of the packaged micro-electronic devices of FIGS. 1-3;

FIG. 6 is a cross-sectional view of an alternate embodiment of a packaged micro-electronic device in which electrical feedthroughs traverse the package's joint;

FIG. 7 is a flow chart that illustrates a method of packaging a micro-electronic device, e.g., to make the packaged micro-electronic device of FIG. 6;

In the Figures and text, like reference numerals indicate elements with similar functions.

In some Figures, relative dimensions of one or more features and/or structures may be exaggerated to more clearly show one or more of the features and/or structures being illustrated.

Herein, various embodiments are described more fully by the Figures and the Detailed Description of Illustrative Embodiments. Nevertheless, the inventions may be embodied in various forms and are not limited to the embodiments described in the Figures and Detailed Description of Illustrative Embodiments.

### DETAILED DESCRIPTION OF ILLUSTRATIVE EMBODIMENTS

Various embodiments include packaged micro-electronic devices with electrical feedthroughs that traverse joints between the different parts of the packages. Herein, an electrical feedthrough is an electrical pathway that connects an electrical device inside the package to the exterior of the package.

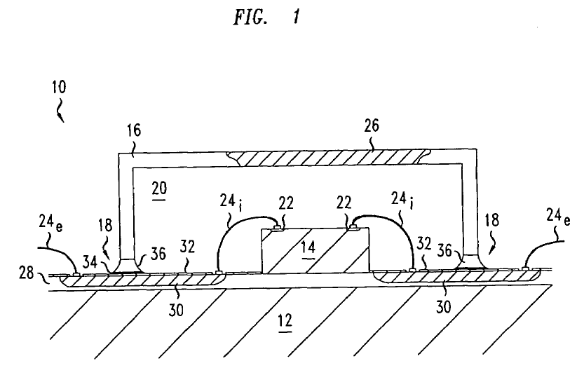

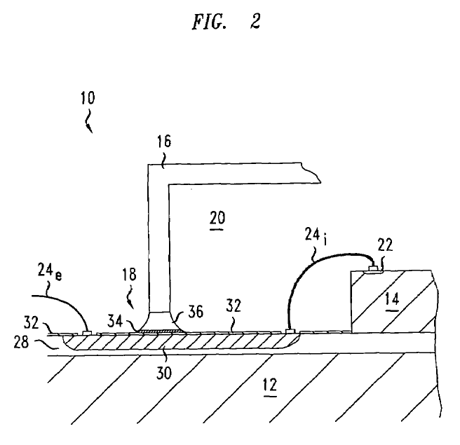

FIGS. 1 and 2 show a portion of a packaged micro-electronic device 10. The packaged micro-electronic device 10 includes a substrate 12, a micro-electronic structure 14, and a housing 16. The packaged micro-electronic device 10 also includes a joint that is located along the length of the perimeter between the substrate 12 and the housing 16.

The substrate 12, housing 16, and a joint 18 may form a hermetic package with a cavity 20 in which the micro-electronic structure 14 is located. In such embodiments, the joint 18 hermetically seals the cavity 20 enclosed between the substrate 12 and the housing 16. Such a hermetic package may maintain a partial vacuum in the cavity 20 or may maintain an inert gas such as nitrogen or argon at standard pressure in the cavity 20. In such embodiments, the substrate 12 has a physical composition suitable to function as a sealing wall of a hermetic package. Exemplary substrates 12 include crystalline semiconductor substrates, e.g., part of a wafer-substrate such as a silicon wafer-substrate.

The micro-electronic structure 14 is a device that performs a function that involves the transmission of electrical signals from the device and/or the receipt of electrical signals at the device. In particular, the micro-electronic structure 14 has conducting pads/connection points 22 that connect to conducting leads 24i internal to the cavity 20. The conducting leads 24i form parts of the conducting pathways for carrying electrical signals between the micro-electronic structure 14 and conducting leads 24e that connect to the exterior of the hermetic package.

The micro-electronic structure 14 may have a variety of forms. Exemplary micro-electronic structures 14 include an integrated micro-electronic circuit that processes electrical signals received from the exterior and/or transmits processed electrical signals to the exterior. Other exemplary micro-electronic structures 14 include one or more micro-electro-mechanical systems (MEMSs) that receive electrical control signals from the exterior. Some exemplary micro-electronic structures 14 are two-dimensional (2D) array-type devices. Examples of 2D array-type devices include 2D arrays of MEMS-controlled optical elements, e.g., adaptive optical 2D mirror or lens arrays, 2D arrays of vertical cavity surface emitting lasers (VCSELs), and 2D arrays of sensors, e.g., light-sensitive diode sensors. In such exemplary micro-electronic structures 14, the housing 16 is configured so that a window 26 passes visible or infrared light between the 2D array of optical elements and the exterior to the package.

The micro-electronic structure 14 may be susceptible to being physically damaged or to having its performance reduced when exposed to ambient environmental conditions. For example, exposure to ambient air or moisture may cause damaging corrosion to the micro-electronic structure 14. Also, exposure to air may cause unacceptable damping of mechanical motion during operation. As an example, the micro-electronic structure 14 may include a movable MEMS structure whose motion would be significantly and undesirably impacted by the presence of a gas at standard pressure. In such embodiments, to avoid such physical damage and/or performance reduction, the package maintains an environment that isolates the micro-electronic structure 14 from ambient external gases.

The micro-electronic structure 14 may also be integrated onto the substrate 12 or may be formed on one or more separate substrates that are mechanically fixed to the substrate 12.

The housing 16 may have a composition suitable to function as a sealing wall of a hermetic package, e.g., a composition impenetrable to ordinary gases. Exemplary housings 16 are made of metal, glass, ceramic, silicon, or a combination of such materials. Some embodiments of the housing 15 may include one or more silica glass windows 26 as already described.

The joint 18 may have a composition suitable to function as part of a sealing wall of a hermetic package. In such embodiments, the sealing joint 18 forms a hermetic seal along the boundary region between the housing 16 and the substrate 12. The joint 18 also includes portions of the electrical feedthroughs that provide electrical connections between the micro-electronic structure 14 and the exterior of the package.

The joint 18 includes an inorganic dielectric layer 28, a metallic layer 30, an inorganic dielectric capping layer 32, a sealing ring 34, and a top joint material 36.

The inorganic dielectric layer 28 is, e.g., a layer of silicon oxide and/or silicon nitride that is formed on a top surface of the substrate 12. The inorganic dielectric layer 28 may be, e.g., a layer of silicon dioxide that was grown on a portion of a silicon wafer substrate 12 and may have, e.g., a thickness of about 2 micrometers (μm) to about 5 μm. An underlying portion of the dielectric layer 28, e.g., one or more micrometers of the same dielectric, may electrically insulate the metallic layer 30 from the substrate 12. In the various embodiments, the thickness of the underlying portion of the dielectric layer 28 is selected as appropriate for the types of the electrical signals carried on the electrical feedthroughs.

In some embodiments, a different inorganic dielectric layer (not shown) underlies the inorganic dielectric layer 28 and electrically insulates the electrical feedthroughs from the underlying substrate 12, e.g., a semiconductor substrate.

The metallic layer 30 is made of separated elongated portions, which are located in trenches in the dielectric layer 28. The elongated portions preferably do not substantially overflow the trenches in which they are located and preferably substantially fill said trenches. Each separate elongated portion is a segment of one of the electrical feedthroughs that traverses the joint 18. Exemplary conducting layers 30 are formed of a metal such as gold (Au), copper (Cu), aluminum (Al), tungsten (W) or are formed of a metal multilayer. Such exemplary conducting layers 30 may or may not include an adhesion layer (e.g., a Ti or Cr adhesion layer).

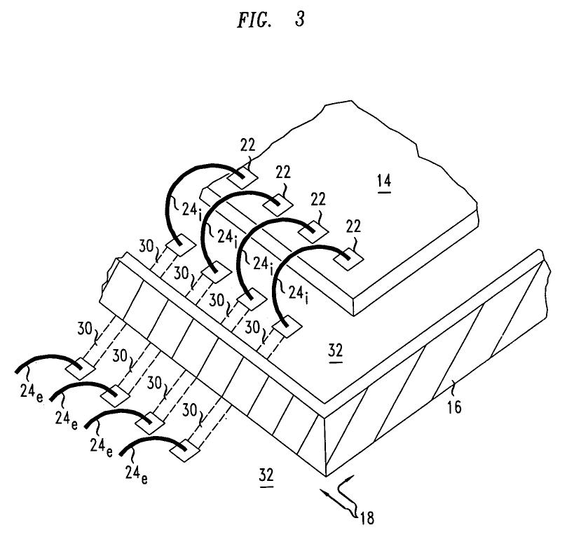

FIGS. 3 and 2 illustrate a part of the sequence of disjoint elongated portions that form the layer 30. The individual elongated portions fill trenches in the dielectric layer 28 and have, e.g., rectangular cross sections. Each spatially separated elongated portion forms the buried portion of the electrical feedthrough between one of the internal metallic electrical leads 24i and a corresponding external metallic electrical lead 24e. The elongated portions are covered by dielectric layer 32, which electrical insulates the elongated portions from the material of the sealing ring 34. Near the ends of the elongated portions, windows through the dielectric layer 32 provide access regions for the internal and external metallic electrical leads 24i, 24e. The internal and external metallic electrical leads 24i, 24e may be, e.g., 1-mil gold wire bonds.

The dielectric capping layer 32 is a conformal layer of inorganic dielectric that electrically insulates and protects the metallic layer 30 from corrosion and damage, i.e., a passifying layer. The dielectric capping layer 32 may be formed, e.g., of silicon dioxide and/or silicon nitride and may have, e.g., a thickness of about 1 μm to about 5 μm.

The sealing ring 34 has a composition that can bond to the top joint material 36 and to the dielectric capping layer 32. In particular, the bonding may enable, e.g., the formation of a hermetic seal.

The top joint material 36 fills the entire length and width of the physical gap between the housing 16 and the sealing ring 34 and bonds to both. For a metallic housing 16, an exemplary top joint material 36 is a conventional metallic solder. For such a top joint material 36, one suitable sealing ring 34 would be metal layers or multilayers, e.g., Ti/Pt/Au, Ti/Ni/Au, Cr/Cu/Au, etc.

In other embodiments (not shown), conducting pads on the bottom surface of the micro-electronic structure 14 connect the micro-electronic structure 14 to the elongated portions of the metallic layer 30 rather than wire bonds. That is, the micro-electronic structure 14 connects to the electrical feedthroughs via solder balls in a flip-chip configuration.

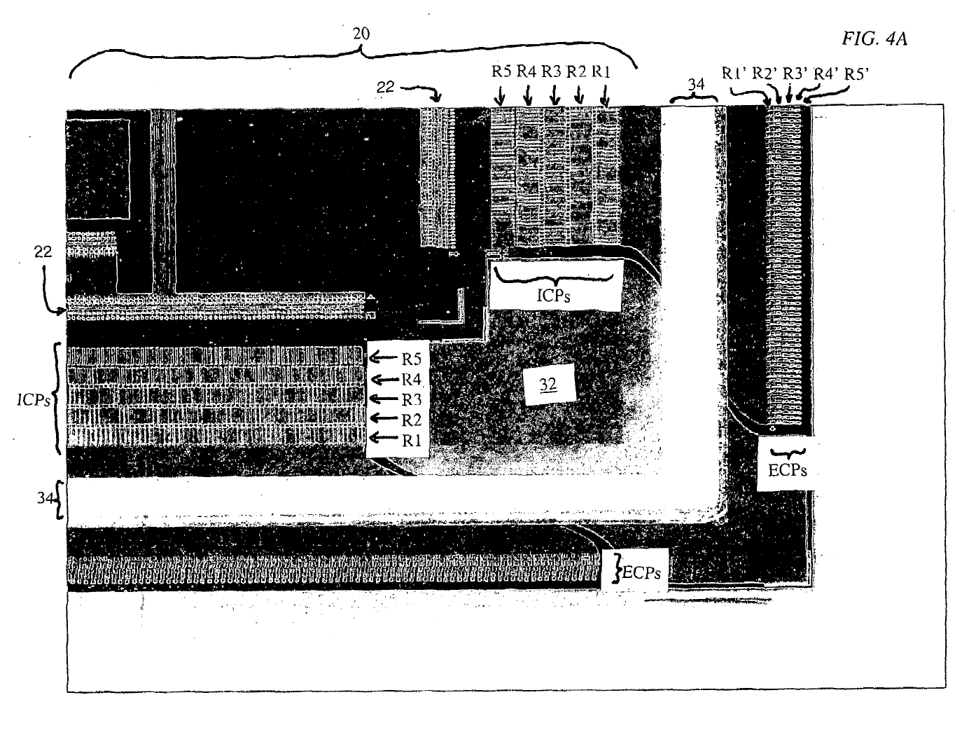

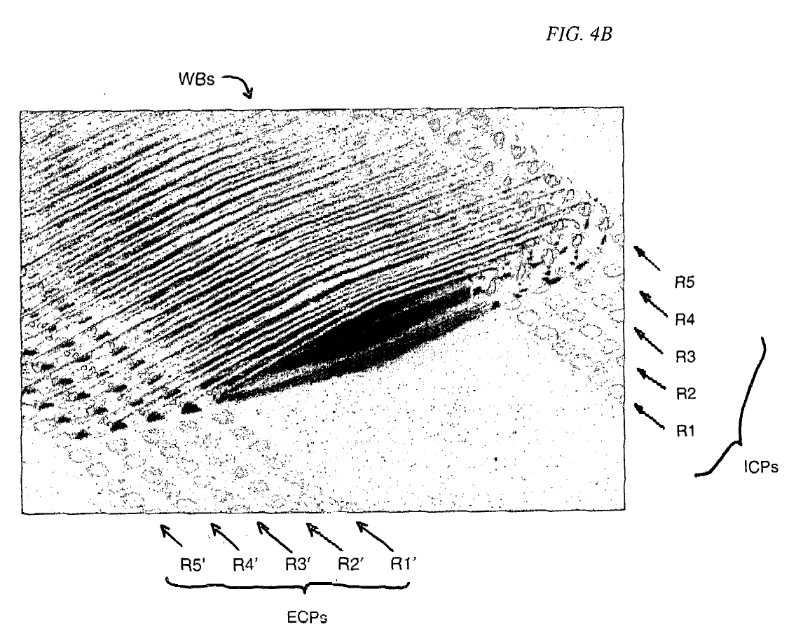

FIG. 4A is a top view of part of an exemplary silicon wafer-substrate 12 that was prepared to test the features of one embodiment of the package of FIGS. 1-3. The shown part of the wafer-substrate 12 includes buried portions of the electrical feedthroughs. The buried portions connect five rows, i.e., R₁, R₂, R₃, R₄, and R₅, of internal contact pads (ICPs) to five rows, i.e., R₁′, R₂′, R₃′, R₄′, and R₅′, of external contact pads (ECPs) thereby providing a high density of electrical feedthroughs. The shown part also has additional contact pads 22 for testing internal wire bond connections (not shown).

The view of the exemplary silicon wafer-substrate 12 of FIG. 4A illustrates that embodiments of the packaged micro-electronic devices 10 of FIGS. 1-3 may support very high linear densities of metallic electrical feedthroughs in the conducting layer 30. Along part of the length of the joint 18, the metallic electrical feedthroughs may have a density of at least 10 per millimeter (mm). Indeed, along part of the length of the joint, the density of such metallic electrical feedthroughs may be 50 or more per mm and may even be as high as 100-120 or more per mm. Also, the metallic electrical feedthroughs may have heights normal to the top surface of the substrate 12 of at least 0.5 micrometers (μm) and may have even heights of 1.0 μm or more, e.g., heights of up to 4.0 μm. Such high densities of large heights for the metallic electrical feedthroughs may be useful for connecting 2D arrays with large numbers of independent electronic devices to the exterior of a hermetic package.

One method for packaging a micro-electronic structure includes the steps of forming electrical portions of electrical feedthroughs on a flat portion of a first part of the package, depositing a layer of dielectric on the portions of the electrical feedthroughs, planarizing the layer of dielectric, and joining together the first and second parts of the package. Such a method produces a package in which electrical pathways traverse the joint between the parts of the package. Unfortunately, such a method may produce a joint that has small gaps therein, because blanket deposition of dielectric often does not completely fill spaces between neighboring portions of electrical feedthroughs. Such gaps are potential paths for gas leakage and can thus, be an obstacle to producing a hermetically sealed package. Furthermore, such gaps may be difficult to avoid as height-to-width aspect ratios of the electrical feedthroughs increase and/or as spacings between neighboring electrical feedthroughs decrease. Indeed, it may be desirable to reduce the spacing between neighboring electrical feedthroughs to increase their densities and/or to increase the height-to-width ratios of electrical feedthroughs to decrease their resistances. Thus, the above-described packaging method may be problematic in some applications of hermetic packages.

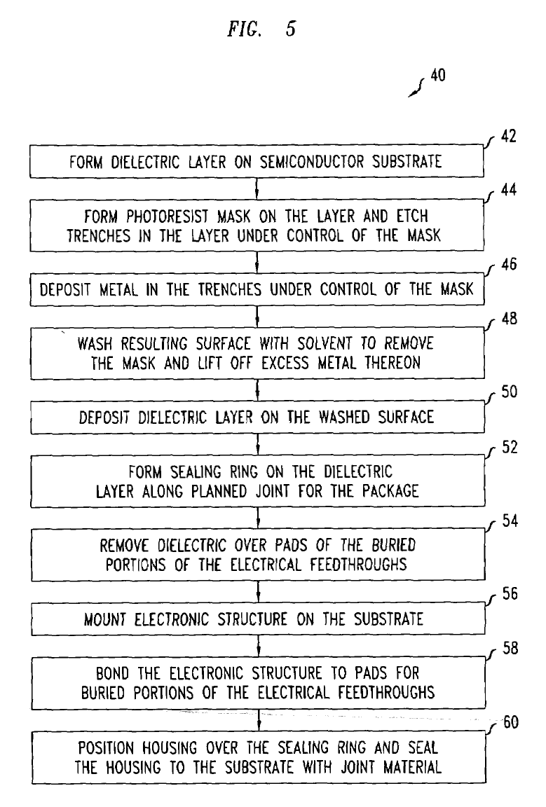

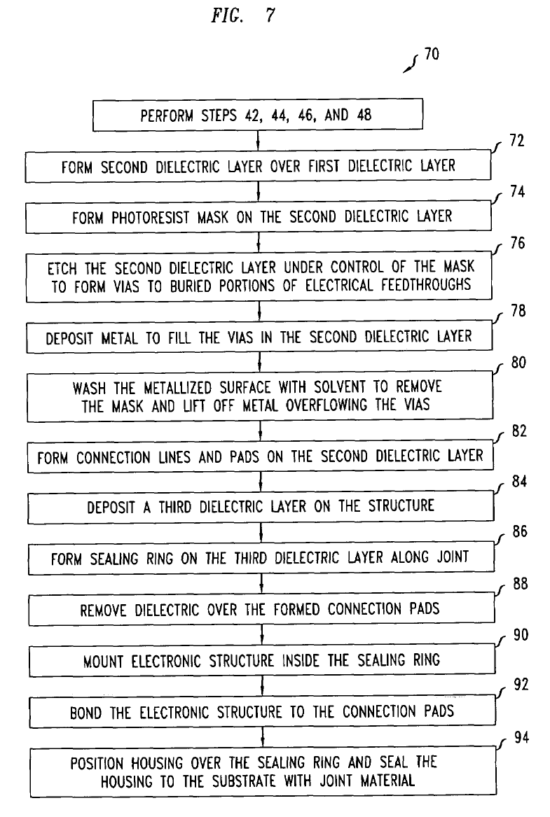

To produce hermetic packages with high electrical feedthrough densities and/or high height-to-width ratios of electrical feedthroughs, some embodiments of the below-described fabrication methods make portions of the electrical feedthroughs differently. In particular, these other methods form portions of the electrical feedthroughs in trenches in a layer of dielectric rather than forming the electrical feedthroughs on a planar surface and then, covering the electrical feedthroughs with a layer of dielectric. For that reason, the packages formed by the below-described methods may be less likely to have empty gaps between the electrical feedthroughs and thus, be less likely to have gas leaks in their sealing joints. These other methods may be performed as illustrated in FIGS. 5 and 7.

FIG. 5 illustrates a method 40 for hermetically packaging a micro-electronic device, e.g., to produce an embodiment of the packaged micro-electronic device 10 of FIGS. 1-3. The packaged micro-electronic device includes a micro-electronic structure, e.g., micro-electronic structure 14, on a portion of a semiconductor substrate, e.g., substrate 12. The micro-electronic structure may be a portion of the semiconductor substrate or may be bonded to one surface of the semiconductor substrate. The packaged micro-electronic device includes a plurality of electrical feedthroughs having buried portions.

The method 40 includes forming an inorganic dielectric layer on the planar top surface of a semiconductor substrate, e.g., the dielectric layer 28 on the semiconductor substrate 12 (step 42). In an exemplary embodiment where the semiconductor substrate is a portion of a silicon wafer, the dielectric layer may be, e.g., a grown silicon oxide layer. The silicon oxide layer may be grown by exposing the surface of the silicon wafer to oxygen and water vapor at high temperature, e.g., about 1,000° Centigrade (C). The inorganic dielectric layer may also be a silicon dioxide or silicon nitride, which is formed, e.g., on the surface of the semiconductor wafer by conventional deposition methods known to those of skill in art.

The method 40 includes forming a patterned photoresist mask on the dielectric layer and then, etching an array trenches in the in the dielectric layer under control of the photoresist mask (step 44). The photoresist mask has an array of elongated windows whose sizes and locations correspond to the trenches desired for the electrical feedthroughs that will electrically connect the micro-electronic structure to the exterior.

A conventional lithographic patterning process may produce the photoresist mask. The etching step may include performing a plasma etch based on a conventional fluorine etching chemistry. The etch may be stopped before the trenches traverse the inorganic dielectric layer so that a suitable amount of same dielectric will remain to electrically insulate the final electrical feedthroughs from an underlying semiconducting substrate, e.g., a silicon wafer-substrate. Rather than stopping the etch prior to traversing the first dielectric layer, a second layer of the same or a different dielectric may be formed on the semiconductor substrate prior to step 42. Then, the second layer will electrically insulate the electrical feedthroughs from the semiconductor substrate.

The method 40 includes depositing metal in the trenches under control of the same photoresist mask (step 46). The metal deposition may involve, e.g., performing a conventional evaporation-deposition, e.g., a deposition of gold. The deposition step stops when the trenches are substantially filled so that the metal and the inorganic dielectric layer have surfaces of about the same height. The metal-filled trenches will form buried portions of electrical feedthroughs, e.g., of the conducting layer 30. The metal-filled trenches will electrically connect the micro-electronic structure being packaged to the exterior of the final package.

The method 40 includes washing the metallized surface of the intermediate structure, which was produced at step 46, with a solvent to remove the photoresist mask (step 48). The solvent-wash also lifts off excess metal that is located on the photoresist mask, e.g. to produce the electrical feedthroughs of the metallic layer 30. After the washing step, the surface of the inorganic dielectric layer and the metal-filled trenches may be flat enough so that a planarization is unnecessary provided that the deposition of metal substantially filled the trenches. The washing step also includes drying the washed structure.

The method 40 includes depositing a layer of inorganic dielectric, e.g., the capping dielectric layer 32, on the surface produced by the liftoff of step 48 (step 50). The inorganic dielectric may be, e.g., silicon oxide and/or silicon nitride and may have a thickness in the range of about 1 μm to 5 μm. Nevertheless, thinner or thicker layers of inorganic dielectric may be used as appropriate for the types of electrical signals that will be sent through the feedthroughs, e.g., as appropriate for the voltages and frequencies of said electrical signals. The deposition step includes, e.g., performing a chemical vapor deposition (CVD) or a sputtering deposition of the inorganic dielectric. The deposition step produces, e.g., a smooth capping layer of the inorganic dielectric on the underlying dielectric layer and metal-filled trenches therein. The capping layer electrically insulates the buried portions of the metal feedthroughs from later deposited materials and may protect said buried portions from corrosion and/or mechanical damage.

The method 40 may include forming a sealing ring, e.g., the sealing ring 34, on the capping dielectric layer along the region for the planned position of the joint between the semiconductor substrate and the housing (step 52). The sealing ring may be formed, e.g., by a shadow mask-controlled deposition so that material of the ring is selectively deposited along the planned position of the sealing joint. The sealing ring made of a material that is compatible with the material that will join the housing and substrate. If a conventional metal-alloy solder is planned for joining the housing and substrate, the sealing ring may be formed from metal multi-layers, e.g., Ti/Pt/Au, Ti/Ni/Au, or Cr/Cu/Au metal multi-layers.

The method 40 includes removing dielectric over the ends of the buried portions of the electrical feedthroughs (step 54). The removal step may include performing a conventional etch under the control of another photoresist mask. The removal step exposes an electrical connection pad at each end of the buried portions of the electrical feedthroughs.

The order of steps 52 and 54 may be inverted in other embodiments of methods for hermetically packaging a micro-electronics device.

The method 40 includes mounting the micro-electronic structure to be packaged, e.g., the micro-electronic structure 14, at the interior of the sealing ring on the surface of the substrate (step 56). The mounting step may include, e.g., gluing the micro-electronic structure onto the surface of the semiconductor substrate. The mounting step includes aligning the micro-electronic structure so that its connection pads are aligned with the electrical connection pads of the buried portions of the electrical feedthroughs.

In alternate embodiments, the mounting of the micro-electronic structure on the semiconductor substrate may be performed at an earlier stage in the packaging method.

In other alternate embodiments, the micro-electronic structure may be incorporated into the semiconductor substrate itself.

The method 40 includes electrically bonding the micro-electronics structure to the electrical feedthroughs (step 58). The step 58 of electrically bonding may involve wire bonding connection pads on the micro-electronic structure to the connection pads for the buried portions of the electrical feedthroughs. The wire bonding may involve, e.g., forming the wire bonds of Au wires, e.g., 1 mil Au wire bonds, using a model 8098 wire bonder, which is manufactured by Kulicke & Soffa Industries of Fort Washington, Pa. In some embodiments, the wire bonds (WBs) are tiered and connection pads are arranged in multiple rows so that the different tiers of wire bonds connect between different rows of the internal and external connection pads, i.e., the ICPs and ECPs. For example, FIG. 4B shows tiered wire bonds WB that electrically link connection pads in rows R1, R2, R3, R4, and R5 to corresponding connection pads in rows R1′, R2′, R3′, R4′, and R5′. Alternately, the step 58 of electrically bonding may involve forming flip-chip interconnections between conducting pads on the micro-electronics structure and the electrical feedthroughs. In such embodiments, connection pads on bottom sides of the micro-electronics structure may connect to exposed parts of the electrical feedthroughs via solder bumps.

The method 40 includes positioning the housing over the sealing ring and sealing the housing to the semiconductor substrate with a joint material, e.g., the top joint material 36, to complete the package's hermetic sealing joint, e.g., sealing joint 18 of FIGS. 1-3 (step 60). The joint material may be, e.g., a solder whose composition is compatible with the material of the housing and the sealing ring. For example, if both the housing and sealing ring are metallic, the joint material may be a conventional metal-alloy solder. Exemplary metal-alloy solders may contain well-known metal alloys such as a Au/Sn eutectic, a Sn/Pb eutectic, etc. The step 60 of sealing may be performed under a vacuum if a partial vacuum is desired in the closed cavity around the micro-electronic structure. Alternately, the step 60 of sealing may be performed in an argon or nitrogen atmosphere if a nonreactive atmosphere is desired in the closed cavity around the micro-electronic structure.

After performing the sealing step, the hermetically packaged micro-electronic device may be stored, transported, or installed as desired. Prior to operation, electrical lines are connected to the exposed external ends of the electrical feedthroughs. These electrical lines may be made by the wire bonding processes already described with respect to the above step 58.

The packaging method 40 of FIG. 4 is capable of producing a hermetic package with a high-density linear of electrical feedthroughs and is capable of producing electrical feedthroughs having buried portions with high height-to-width aspect ratios. Each of these features can help to increase the surface density of electrical feedthroughs without increasing associated resistances unacceptably. For example, along part of the length of the sealing joint between the housing and substrate, the packaging method 40 may produce metallic electrical feedthroughs having a density of 10 or more per millimeter (mm), 50 or more per mm, or even 100-120 or more per mm. Also, such buried portions of the metallic electrical feedthroughs may have heights of at least 0.5 μm or may even have heights of 1.0 μm or more in a direction normal to the top surface of the semiconductor substrate, e.g., heights of 1.0 μm to 4.0 μm. Electrical feedthroughs having such high densities and large heights may be useful for connecting large 2D arrays of electronic devices to the exterior of a hermetic package.

Since there is an inherent mismatch between the thermal expansivity of dielectrics and conductors, temperature variations can cause delaminations at the interfaces between electrical feedthroughs and dielectrics in the packaged micro-electronic devices 10 of FIGS. 1-3 and 4A. Such delaminations can produce paths for gas leakage and thus, can cause ruptures of package hermeticities. That is, temperature variations during manufacture and/or during operation can produce such ruptures. For that reason, some packages have sealing joints with features that reduce the risk of such delaminations. Such features may improve manufacturing yields, reliabilities, and/or lifetimes of such hermetically packaged micro-electronic devices.

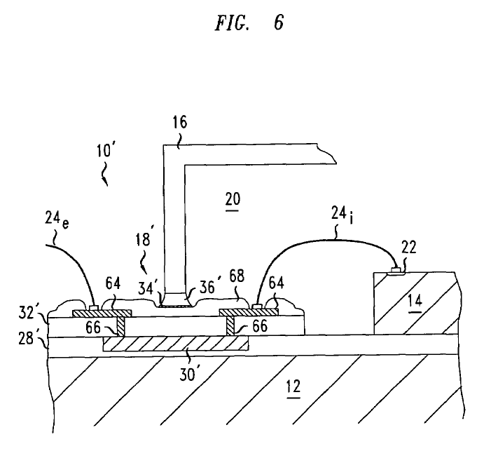

FIG. 6 shows a portion of a hermetically packaged micro-electronic device 10′. The packaged micro-electronic device 10′ includes semiconductor wafer-substrate 12, micro-electronic structure 14, housing 16, and the sealing joint 18′. The sealing joint 18′ is located along the length of the perimeter where the semiconductor wafer-substrate 12 seals to the housing 16. The packaged micro-electronic device 10′ has features to improve the resistance of a sealing joint 18′ to such unwanted delaminations.

The sealing joint 18′ includes inorganic dielectric layer 28′, conducting layer 30′, dielectric layer 32′, sealing ring 34′, and joint material 36′. The elements 28′, 30′, 32′, 34′, and 36′ of the sealing joint 18′ have functions and compositions that are similar to those of respective elements 28, 30, 32, 34, 36, and 18 of FIGS. 1-3. For example, the conducting layer 30′ is a sequence of spatially disjoint elongated portions, which are located in trenches in the dielectric layer 28′. The elongated portions form the buried portions of the electrical feedthroughs. As described below, some of the elements 28′, 30′, 32′, 34′, 36′, and/or 18 may differ somewhat in composition and/or dimensions from the corresponding elements 28, 30, 32, 34, 36, and 18 of FIGS. 1-3.

In the sealing joint 18′, the conducting layer 30′ may have a thermal coefficient of expansion that better matches to the thermal coefficients of expansion of the dielectric layers 28′, 32′. For example, tungsten (W) and heavily doped semiconductor have thermal expansions that better match those of surrounding dielectrics than gold. A better match between the thermal coefficients of expansion can reduce the potential for catastrophic delaminations between the layers 28′ and 30′ and between the layers 30′ and 32′ thereby lower the risk of hermeticity ruptures for the packaged micro-electronic device 10′. However, conductors with lower thermal expansions may also have lower electrical conductivity than metals like gold. The associated downside of having lower electrical conductivities can be partially offset by making buried portions of the electrical feedthroughs in the conducting layer 30′ shorter and/or by increasing the cross-sectional area of said buried portions, e.g., by increasing the height-to-width aspect ratio of the buried portions of the electrical feedthroughs.

In the sealing joint 18′, the buried portions of the electrical feedthroughs may also have dimensions that reduce stresses caused by temperature variations. For example, the individual elongated portions of the conducting layer 30′ may have a smaller cross-sectional areas than the individual elongated portions of the conducting layer 30 of FIGS. 1-3 in those embodiments. A buried conducting layer having a smaller cross-sectional area should expand and contract less in response to a temperature change and should produce smaller stresses on adjacent dielectric layers in response to such temperature variations. For that reason, catastrophic delaminations and/or cracks are expected to be less likely in embodiments where the elongated portions of the conducting layer 30′ have smaller cross-sectional areas. While these embodiments may produce buried portions of electrical feedthroughs with higher electrical resistances, the resistance increases can be partially offset by making the buried portions of said electrical feedthroughs shorter.

Also, in the sealing joint 18′, the individual elongated portions of the conducting layer 30′ may have circumferences that are smaller than the circumferences of the corresponding elongated portions of the conducting layer 30 of FIGS. 1-3. Then, the interface between the conducting layer 30′ and the surrounding dielectric is reduced. Since gas leakage is expected to occur at such interfaces, the reduction of the interface area would also be expected to lower the probability of hermeticity ruptures. While such embodiments may again produce buried portions of electrical feedthroughs with higher electrical resistances, such resistance increases can be partially offset by making the buried portions of the electrical feedthroughs shorter.

The sealing joint 18′ also includes a top conducting layer 64, metal filled vias 66, a top inorganic dielectric layer 68, a sealing ring 34′, and joint material 36′. The top conducting layer 64 provides electrical connections between the individual buried elongated portions of the electrical feedthroughs of the conducting layer 30′ and the internal and external leads 24i, 24e. The top conducting layer 64 may be formed of materials of higher conductivity than the material of the conducting layer 30′, because delaminations of the conducting layer 64 do not necessarily cause ruptures of the hermeticity of the package. Exemplary materials for the top conducting layer 64 may include metals such as gold, aluminum, or copper. The metal filled vias 66 electrical connect the buried portions of the electrical feedthroughs in the conducting layer 30′ to the segments the top conducting layer 64. The vias 66 may be filled with metals, e.g., tungsten. The inorganic dielectric layer 68 may form part of the sealing joint 18′ and may provide additional electrical insulation between the conducting layer 30′ and the sealing ring 34′ and joint material 36′, which may be a metal-alloy solder.

FIG. 7 illustrates a method 70 for fabricating a hermetic package in which electrical feedthroughs have buried portions. The method 70 uses multiple metal layers to make the electrical feedthroughs. For example, the method 70 may fabricate the packaged micro-electronic device 10′ of FIG. 6

The method 70 includes performing the steps 42, 44, 46, and 48 substantially as described with respect to method 40 of FIG. 5. At the completion of the steps 42, 44, 46, and 48, the method 70 has produced a first dielectric layer, e.g., the dielectric layer 28′ on the semiconductor substrate 12, with a first conducting layer buried therein, e.g., the conducting layer 30′. The first conducting layer consists of a linear lateral array of elongated conducting sections, i.e., of heavily doped semiconductor or metal, e.g., W, Cu, Al, or Au. Each elongated conducting section fills a corresponding trench in the first inorganic dielectric layer, e.g., the dielectric layer 28′. The conductor-filled trenches will form the buried portions of electrical feedthroughs, e.g., in the packaged micro-electronic device 10′ of FIG. 6.

As above, the buried portions of the electrical feedthroughs may have a density of at least 10 per millimeter (mm), and the density may be 50 or more per mm and may even be as high as 100-120 or more per mm. Also, the buried portions of the electrical feedthroughs may have heights normal to the top surface of the substrate of at least 0.5 μm and may even have heights of 1.0 μm or more, e.g., heights of 1.0 μm to 4.0 μm.

Next, the method 70 includes forming a second inorganic dielectric layer, e.g., the dielectric layer 32′, on the dielectric layer in which the conductor-filled trenches are located (step 72). The second dielectric layer may be, e.g., a conventionally deposited silicon dioxide and/or a silicon nitride layer. The second inorganic dielectric layer may have a thickness of about 1 μm to about 5 μm. The appropriate thickness of the second inorganic dielectric depends on the nature of electrical signals that will be carried by the electrical feedthroughs.

The method 70 includes forming a photoresist mask on the second dielectric layer (step 74). The photoresist mask may be formed by a variety of conventional processes known to those of skill in the art, e.g., lithographically patterning. The photoresist mask has windows for the locations of vias that will electrically connect ends of buried portions of the electrical feedthroughs of the first conducting layer, e.g., the vias 66 of FIG. 6.

The method 70 includes dry or wet etching the second dielectric layer under the control of the photoresist mask (step 76). The dry or wet etching step produces the vertical vias. One via connects to each end of the buried portion of an electrical feedthrough of the first conducting layer.

The method 70 includes depositing metal under control of the same photoresist mask so as to fill the vias in the second dielectric layer (step 78). The deposition may involve an evaporation-deposition of titanium, gold, tungsten, or another metal, e.g., to form W or Ti/W plugs.

The method 70 includes washing the metallized surface of the intermediate structure from step 78 with a solvent to remove the photoresist mask (step 80). The solvent-wash also lifts off metal that overflows boundaries of the vias. After the solvent-wash, metal-filled vias remain, and the metal-filled vias connect to the ends of the buried portions of the electrical feedthroughs. The solvent-wash may include a step of drying the resulting intermediate structure.

Next, the method 70 includes forming a top metal layer, e.g., the top conducting layer 64, on the second dielectric layer (step 82). The top metal layer consists of connection pads and connection lines that link to the metal-filled vias. That is, one connection line and pad of the top metal layer connects to each end of the buried part of an electrical feedthrough of the first conducting layer via the metal-filled vias. One set of the connection lines and pads of the top metal layer will be external to the final package, and a second set of the connection lines and pads of the top metal layer will be internal to the final package. The top metal layer may be formed by two alternative processes.

The first process produces the top metal layer on the surface of the second dielectric layer. The first process includes performing an evaporation deposition of metal onto the top surface of the second dielectric layer under the control of another photoresist mask. The first process also includes performing a solvent-wash to remove the photoresist mask and to lift off excess metal, which is located on the photoresist mask. The resulting intermediate structure is then dried.

The second process produces a buried top metal layer on the top surface of the second dielectric layer. The second process includes depositing a third dielectric layer on the second dielectric layer, e.g., a silicon dioxide or silicon nitride. The second process includes forming a lithographically patterned photoresist mask on the third dielectric layer and then, etching the third dielectric layer to produce an array of trenches through the third dielectric layer. The second process also includes performing an evaporation deposition of metal on the third dielectric layer without removing the photoresist mask. The second process also includes performing a solvent-wash of the resulting intermediate structure to remove the photoresist mask and to lift off excess metal that is located on the photoresist. The second process also includes drying the resulting intermediate structure. The second process may exploit techniques similar to those of above-described steps 72, 74, 76, and 80.

The first process may be preferable to the second process where a thin top metal layer is desired, because a thin blanket dielectric coating may provide sufficient passivation or protective coverage of the electrical connection paths of such a thin top metal layer.

The first process may also be preferable to the second process where the top metal layer is thick and would produce stresses that interfere with a buried construction.

The second process may also be preferable to the first process if high reliability against breaches of hermeticity are desired. In particular, the second process produces a structure that is less likely to enable gas to leak in or out. For example, burying the top conducting layer may lower the risk of delaminations by the last dielectric layer.

The method 70 may include depositing a third inorganic dielectric layer, e.g., the dielectric layer 68, over the same surface of the structure (step 84). The third inorganic dielectric layer may function as a passivating layer for the top metal layer. The third inorganic dielectric layer may be, e.g., a silicon dioxide and/or silicon nitride and may have, e.g., a thickness in the range of 0.5 to 1 μm. or more. The third inorganic dielectric layer may be deposited by one of the above-described processes for depositing inorganic dielectric or may be deposited by other processes known to those of skill in the art.

The method 70 may also include forming a sealing ring, e.g., the sealing ring 34′, on the top dielectric layer along a planned joint region thereof (step 86). The formation of the sealing ring may involve performing a conventional deposition process under control of a shadow mask. The sealing ring is formed of a material suitable for bonding to a selected top joint material. When a conventional metal solder is planned for the top joint material, the sealing ring may be, e.g., Ti/Ni/Au, Ti/Pt/Au, Cr/Cu/Au, etc.

The method 70 may include removing any dielectric that covers the electrical connection pads of the top metal layer (step 88). The removal step 88 may include performing a conventional etch under the control of another photoresist mask.

The order of steps 86 and 88 may be inverted in other embodiments of methods of fabricating hermetic packages in which electrical feedthroughs have buried portions.

The method 70 may include mounting the micro-electronic structure that is to be packaged, e.g., micro-electronic structure 14. The micro-electronic structure is mounted inside the sealing ring on the semiconductor substrate (step 90). The mounting step may be, e.g., performed as described in above step 56.

In alternate embodiments, the step of mounting of the micro-electronic structure on the semiconductor substrate is performed at an earlier stage in the packaging method.

In other alternate embodiments, the micro-electronic structure is incorporated into the semiconductor substrate.

The method 70 includes bonding connection pads of the micro-electronic structure to the connection pads of the electrical feedthroughs, i.e., the connection pads of the top metal layer (step 92). The step 92 may involve performing wire bonding or flip-chip bonding as already described with respect to step 58 of FIG. 5.

The method 70 includes positioning the housing over the sealing ring and sealing the housing to the substrate with a top joint material to complete the package's hermetic sealing joint, e.g., the sealing joint 18′ (step 94). In step 94, the top joint material may be a solder whose composition is compatible with the materials of the housing and the sealing ring. If both the housing and sealing ring are metallic, the top joint material may be a conventional metal-alloy solder, e.g., a solder comprising a lead, tin, and/or antimony alloy. The step 94 of sealing may be performed under a vacuum or under a non-reactive atmosphere, e.g., an argon or nitrogen atmosphere, as desired.

From the disclosure, drawings, and claims, other embodiments of the invention will be apparent to those skilled in the art.

What is claimed is:

1. An apparatus, comprising:
a substrate having a top surface;
a housing having an inner surface, the top and inner surfaces being located to form a cavity between the housing and the substrate;
a joint between the top surface and the housing;
a micro-electronic structure being exposed to the cavity and being located between the substrate and housing;
metal electrical feedthroughs traversing the joint and being connected to the micro-electronic structure; and
a dielectric layer located over the substrate, portions of the electrical feedthroughs being located in trenches in the dielectric layer; and
wherein the metal electrical feedthroughs have a density along part of the joint of at least 10 per millimeter.

2. The apparatus of claim 1, wherein the metallic electrical feedthroughs have heights normal to the top surface of at least 0.5 micro-meters.

3. The apparatus of claim 1, the metal electrical feedthroughs have a density along part of the joint of at least 50 per millimeter.

4. The apparatus of claim 2, wherein the joint, housing, and substrate hermetically seal the cavity.

5. The apparatus of claim 4, wherein the micro-electronic structure includes a two-dimension array of optical devices and the housing has a window for passing visible or infrared light through the housing.

6. An apparatus, comprising:
a semiconductor substrate having a top surface;
a housing having an inner surface, the top and inner surfaces being located to form a cavity between the housing and the substrate;
a joint between the top surface of the substrate and the housing;
a micro-electronic structure being exposed to the cavity and being located between the substrate and housing;
electrical feedthroughs traversing the joint and being connected to the micro-electronic structure; and
a dielectric layer located over the substrate, portions of the electrical feedthroughs that traverse the joint being located in trenches in the dielectric layer, the dielectric layer insulating the electrical feedthroughs from the substrate.

7. The apparatus of claim 6, wherein the joint, housing, and substrate hermetically seal the cavity.

8. The apparatus of claim 6, wherein the joint includes a solder joint located between the housing and the dielectric layer.

9. The apparatus of claim 6, wherein the joint comprises:
a portion of a second dielectric layer located over the other dielectric layer; and
wherein the electrical feedthroughs include conducting paths located on the second dielectric layer, the conducting paths being physically connecting by metal-filled vias to the portions of the electrical feedthroughs in the trenches.

10. The apparatus of claim 6, wherein the micro-electronic structure includes a two-dimensional array of MEMS devices, VCSELs, or sensors.

11. The apparatus of claim 6, wherein the micro-electronic structure includes a 2D array of MEMS-controlled optical elements and the housing comprises a window capable of passing infrared or visible light.

12. A method of packaging a micro-electronic structure, comprising:
forming electrical feedthroughs that connect to a micro-electronic structure located over a substrate; and
forming a package by joining a housing to the substrate such that the micro-electronic structure is exposed to a cavity formed between the housing and the substrate; and
wherein the forming of each electrical feedthrough includes depositing conducting material a trench in a dielectric layer, the dielectric layer being located over the substrate; and
wherein the joining includes forming a joint between the housing and the substrate, a portion of each trench traversing the joint.

13. The method of claim 12, wherein the forming electrical feedthroughs produces a density of at least 10 of said feedthroughs per millimeter along part of the joint.

14. The method of claim 13, wherein the formed electrical feedthroughs have heights of at least 0.5 micrometers.

15. The method of claim 12, wherein the forming of each electrical feedthrough includes forming a metallic path over the dielectric layer that electrically connects to the conducting material in one of the trenches; and
electrically connecting the paths to the electronic structure.

16. The method of claim 12, wherein the joining includes hermetically sealing the cavity.

17. The method of claim 12, further comprising
forming a second dielectric layer over the other dielectric layer and
forming a pattern of metal paths on the second dielectric layer such that each metal path is connected by a metal-filled via to the conducting material in one of the trenches.

18. The method of claim 12, wherein the micro-electronic structure includes a two-dimensional array of MEMS devices, VCSELs, or sensors.

19. The method of claim 12, wherein the micro-electronic structure includes a 2D array of MEMS-controlled optical elements and the housing comprises a window for passing visible or infrared light between the array and a region exterior to the package.

20. The method of claim 12, wherein the step of joining a housing to the substrate includes making a solder joint between the housing and the dielectric layer.
